(19) United States
(12) Patent Application Publication
(10) Pub. No.: US 2025/0361141 A1
(43) Pub. Date: Nov. 27, 2025

(54) MICROELECTROMECHANICAL DEVICE FOR INTERACTION WITH A FLUID

(71) Applicant: Robert Bosch GmbH, Stuttgart (DE)

(72) Inventors: Anton Melnikov, Dresden (DE); Maximilian Sommer, Dresden (DE); Alexander Sorger, Dresden (DE); Jens Schindele, Kirchentellinsfurt (DE)

(21) Appl. No.: 19/171,421

(22) Filed: Apr. 7, 2025

(30) Foreign Application Priority Data
Apr. 9, 2024 (DE) 10 2024 203 209.3

(51) Int. Cl. B81B 7/00

(52) U.S. Cl. CPC B81B 7/0061; B81B 2201/0257; B81B 2201/036; B81B 2203/0315; B81B 2203/0338

(57) ABSTRACT

A microelectromechanical device for interaction with a fluid. A displacer structure, wherein the displacer structure is arranged in a cavity, wherein the displacer structure comprises a movable lamella that is deflectable for interaction with a fluid pressure in a pressure region of a cavity, wherein the lamella has at least one edge region, wherein the edge region of the lamella is movable along at least one boundary surface of the cavity when the lamella is deflected, wherein a flow channel is formed between the boundary surface and the edge region, wherein fluid can flow out of the pressure region via the flow channel, wherein the edge region and/or the boundary surface comprise means that make it more difficult for fluid to flow out of the pressure region via the flow channel.

### FIELD

The present invention relates to a microelectromechanical device for interaction with a fluid.

### BACKGROUND INFORMATION

MEMS speakers which are designed as planar structures are described in U.S. Patent Application Publication No. US 2021/297787, wherein a vibratable membrane is excited in such a way that a fluid is displaced and/or compressed vertically to the membrane plane. The membrane is typically excited by means of a piezoelectric or electrostatic effect.

### SUMMARY

An object of the present invention is to provide an improved microelectromechanical device for interaction with a fluid.

The object of may be achieved by certain features of the present invention.

The present invention provides a microelectromechanical device for interaction with a fluid. For example, the device may be designed to generate a fluid pressure with a displacer structure. According to an example embodiment of the present invention, the displacer structure is arranged in a cavity. The displacer structure has a movable lamella, which can be fastened to a carrier. For interaction with a fluid pressure in a pressure region of the cavity, in particular in a subcavity of the cavity, the lamella is deflectable in the direction of the pressure region of the cavity and/or in the direction away from the pressure region. The lamella has a width, a length, and a thickness, wherein an edge region is formed on a side edge of the lamella. When the lamella is deflected, in particular deflected actively, the edge region of the lamella is moved along at least one boundary surface of the cavity in order to generate a fluid pressure in the pressure region. In addition, other means can also be used to generate an increased pressure in the fluid. In this situation, the lamella is moved away from the pressure region by the pressure of the fluid. In both situations, a flow channel, via which fluid can flow out of the pressure region, is formed between the boundary surface and the edge region. The edge region and/or the boundary surface comprise means that make it more difficult for fluid to flow out of the pressure region via the flow channel. The lamella can comprise electrostatic and/or piezoelectric elements, by means of which the lamella can be moved in a desired direction. The fluid may be liquid or gaseous.

The means are used to make it more difficult for the fluid to flow out of the pressure region via the flow channel. This can increase the pressure buildup in the case of an actively movable lamella, such as in a Mems speaker or a Mems pump. In addition, the pressure drop can be slowed in the case of a passive lamella, such as in a pressure sensor. Improvement of the function of the device is thus achieved.

According to an example embodiment of the present invention, the edge region has a gap distance to a boundary surface, which gap distance is to be as small as possible. The smaller the gap distance between the edge region and the boundary surface, the less fluid can flow out of the pressure region. However, the reduction of the gap distance is limited for production-related and/or technical reasons. In addition, the gap distance can also vary during the movement of the lamella depending on the movement direction in which the edge region of the lamella is moved relative to the boundary surface when pressure is generated.

In order to make it possible for the device to function well, but also from the perspective of manufacturing aspects, movable elements of the device, that is, in particular the displacer structure, have a sufficiently large gap distance to an edge region, such as a further lamella, a chip frame, a chip cover, or a chip bottom. However, when the pressure is built up, for example in the case of a MEMS speaker, this can have the result that a leakage flow flows out via the gap distance on the side facing the ear. This reduces the sound pressure arriving at the inner ear. The means that make it more difficult for the fluid to flow out of the pressure region via the flow channel are provided in order to minimize this effect.

According to an example embodiment of the present invention, the means can in particular be designed to lengthen the flow path. A lengthened flow path results in greater flow resistance and thus in the fluid flowing more slowly out of the pressure region. The flow path can be lengthened, for example, by thickening the lamella. The thickening, that is, the thicker formation of the lamina, is preferably to be limited to the edge region since the stiffness of the lamina would otherwise increase. Increased stiffness has the disadvantage that a high sound pressure level is more difficult to achieve. Consequently, it is advantageous to limit the thickening of the lamella to a specified distance to the edge region. The thickening of the lamella has the result that the fluid region in which the edge region of the lamella has a small distance to the boundary surface is lengthened in the flow direction.

In one example embodiment of the present invention, the lamella comprises a cross piece (web) in the edge region, which cross piece projects laterally beyond at least one side surface of the lamella. Preferably, the cross piece projects laterally on two opposing side surfaces of the lamella. For example, forming the cross piece in the edge region of the lamella provides a lamella with an edge region that is formed in a T-shape in the cross-section perpendicular to the side surface of the lamella. The cross piece can be plate-shaped and preferably be arranged perpendicularly to the surface extension of the lamella.

The gap distance between the edge region of the lamella and the boundary surface can be between 0.01 μm and 100 μm, preferably between 0.1 μm and 30 μm, particularly preferably between 1 μm and 10 μm.

The thickening, and in particular the cross piece, can have a thickness, when viewed in the longitudinal extension of the lamella, that can be in a range of 0.1 μm to 300 μm, in particular between 0.5 μm and 50 μm, particularly preferably between 1 μm and 10 μm. The length of the thickening, in particular the length of the cross piece along the flow direction, can be in the range of 0.1 μm to 300 μm, in particular 1 μm to 70 μm, particularly preferably between 5 μm to 40 μm. The length of the lamella can be between 10 μm and 50 mm, in particular between 100 μm and 10 mm, in particular between 200 μm and 5 mm, and particularly preferably between 300 μm and 3 mm. The thickness of the lamella can be in the range between 0.1 μm to 300 μm, in particular between 1 μm to 400 μm, particularly preferably between 2 μm and 30 μm.

n one example embodiment of the present invention, the widened formation of the edge region, in particular the cross piece, extends at least along 50% of a length of the edge region of the lamella. Preferably, the widened formation of the edge region, in particular the cross piece, extends over an entire length of the edge region of the lamella. The longer the widened formation of the edge region, in particular of the cross piece, the greater the resistance for the fluid when leaving the pressure region.

In one example embodiment of the present invention, the lamella has multiple edge regions, which are moved along assigned boundary surfaces when the lamella is deflected actively or passively. In order to make it more difficult for fluid to flow out of the pressure region, it is advantageous to form a resistance structure, that is, a thickened edge region and/or a cross piece that lengthens the flow channel, on as many of these edge regions as possible. Depending on the chosen embodiment, all edge regions of the lamella that are movable can be formed with corresponding resistance structures.

According to an example embodiment of the present invention, the lamella can be fastened to a carrier on one side or on both sides or on multiple sides. In addition, the lamella can be fastened to the carrier via connecting elements. The proposed resistance structures are advantageous regardless of the type of fastening or mounting of the lamella on the carrier.

In one example embodiment of the present invention, the thickness of the thickened edge region, in particular the width of the cross piece, varies along the edge region of the lamella. For example, the thickness of the thickened edge region, in particular the width of the cross piece, can increase perpendicularly to the side surface of the lamella from a fastened end of the lamella in the direction of a free end of the lamella. In this way, an optimization between an increase in the stiffness of the lamella and an enlargement of the flow channel can be adjusted.

In a further example embodiment of the present invention, a surface of the thickened edge region, in particular of the cross piece, that faces the boundary surface has a shape that is domed in the direction of the boundary surface. The domed shape can serve to ensure that, when the lamella moves, the thickened edge region, in particular the cross piece, does not come into contact with the boundary surface despite a small gap distance. For example, in a cross-section of the movement direction of the lamella, the surface of the thickened edge region, in particular of the cross piece, can have a shape that is domed in the direction toward the boundary surface. For example, the domed shape may be a circular shape. For example, the domed surface of the thickened edge region, in particular the domed surface of the cross piece, may be a cylinder surface. Depending on the chosen embodiment, the radius of the cylinder surface may also vary.

In one example embodiment of the present invention, the thickened edge region, in particular the cross piece, faces a boundary surface on multiple sides of the thickened edge region or of the cross piece. In this way, a lengthened flow channel is formed. Forming the flow channel in this way also achieves a change in the flow direction within the angled flow channel.

This makes an additional increase in the flow resistance possible.

Depending on the chosen embodiment of the present invention, a lamella can have multiple spaced-apart thickened regions and/or multiple spaced-apart cross pieces in the edge region. Multiple boundary surfaces can be assigned to the multiple thickened regions and/or the multiple cross pieces so that a lengthened flow channel is formed in total.

The multiple thickened regions and/or the multiple cross pieces can be arranged to be spaced apart from one another along a longitudinal direction or transverse direction of the lamella. For example, the thickened regions and/or the multiple cross pieces can be arranged in parallel with one another.

The lamellae can have thickened regions, in particular cross pieces, at multiple edge regions. The boundary surfaces can be arranged on the multiple edge regions. If, for example, a lamella is fastened at an edge region to a carrier, thickened regions, in particular cross pieces, can be formed on each of the three remaining free edge regions, wherein a boundary surface is assigned to each of the free edge regions. A lengthened flow channel can thus be formed in all edge regions via which it is possible for fluid to flow out of the pressure region.

In a further example embodiment of the present invention, the boundary surfaces are formed in the form of further cross pieces, wherein the cross pieces of the lamellae and the further cross pieces overlap along the direction of the cross pieces and form a meandering flow channel. This also increases the flow resistance and makes it more difficult for fluid to flow out of the pressure region.

In a further example embodiment of the present invention, the boundary surface is formed by a wall of the cavity and/or by a surface of a further lamella. A flow channel can thus be formed not only between a lamella and a wall of the cavity but also between two lamellae of the cavity. For example, the boundary surface can be formed by a thickened edge region of a further lamella and/or by a cross piece of a further lamella.

In a further example embodiment of the present invention, at least two lamellae are arranged in the cavity. The two lamellae thus divide the cavity into three subcavities. Two neighboring subcavities are in each case connected to each other via a flow channel, which is formed between the edge regions of the lamella and boundary surfaces, in particular walls of the cavity. In this way, the lamellae are movable in such a way that fluid is conveyed from a first subcavity to the third subcavity.

In a further example embodiment of the present invention, at least two lamellae are arranged in the cavity, wherein a flow channel is formed between the lamellae. The two lamellae thus divide the cavity into two subcavities, which are connected to each other via the flow channel between the two lamellae. The lamellae are movable in such a way that fluid is conveyed from a first subcavity to a second subcavity.

In a further example embodiment of the present invention, the lamellae are fastened to different sidewalls of the cavity. In particular, the lamellae can be fastened with one end and/or with two ends to different sides of the cavity. This arrangement can be used to realize differently formed subcavities that make it possible to convey fluid, in particular to increase pressure. A flow channel can be formed between two lamellae, for example.

The present invention is described below with reference to exemplary figures.

### BRIEF DESCRIPTION OF THE DRAWINGS

FIG. 1A to 1E show schematic illustrations of displacer structures and partial cross-sections of a microelectromechanical device, according to an example embodiment of the present invention.

FIG. 2A to 2E show a perspective illustration of a displacer structure, various partial cross-sections of various displacer structures, and a schematic partial illustration of a microelectromechanical device, according to example embodiment of the present invention.

FIG. 3A to 3F show example embodiments of displacer structures, according to the present invention.

FIG. 4A to 4E show further example embodiments of displacer structures, according to the present invention.

FIG. 5A to 5F show further example embodiments of displacer structures, according to the present invention.

FIG. 6A and 6B show schematic partial cross-sections through an example embodiment of a microelectromechanical device of the present invention.

FIG. 7A to 7C show schematic partial cross-sections of further example embodiments of microelectromechanical devices, according to the present invention.

FIG. 8A and 8B show further example embodiments of microelectromechanical devices with multiple displacer structures in one chamber, according to the present invention.

FIG. 9A and 9B show further example embodiments of microelectromechanical devices with multiple displacer structures fastened to opposing sidewalls, according to the present invention.

FIG. 10 show a further example embodiment of a microelectromechanical device, according to the present invention.

### DETAILED DESCRIPTION OF EXAMPLE EMBODIMENTS

Microelectromechanical devices, i.e., MEMS components, can be multilayered layer structures. Such MEMS components can be obtained, for example, by processing semiconductor material at the wafer level, which can also include a combination of multiple wafers and/or the deposition of layers onto wafer planes. Embodiment examples described here can relate to layer stacks with multiple layers. However, layers described in this context may, but do not necessarily have to, be a single layer, but, in embodiment examples, they may easily comprise two, three, or more layers and be understood as a layer composite. Thus, both layers from the material of which a movable element is formed and layers between which a movable element is arranged can be formed with multiple layers, which can be designed, for example, as at least a part of a wafer and can comprise multiple layers of material, for example for implementing physical, chemical, and/or electrical functions. Some of the embodiment examples described here are described in connection with a loudspeaker configuration or a loudspeaker function of a corresponding MEMS component. It is understood that these statements, with the exception of the alternative or additional function of a sensor-based evaluation of the MEMS component or of the movement or position of movable elements thereof, can be transferred to a microphone configuration or microphone function of the MEMS component so that such microphones represent, without restriction, further embodiment examples of the present invention. Furthermore, other applications of MEMS are also within the scope of embodiment examples described here, such as micropumps, ultrasonic transducers, or other MEMS-based applications that are related to moving fluid. For example, embodiment examples can relate to a movement of actuators that can interact with a fluid, among other things. Embodiment examples relate to an application of electrostatic forces for deflecting a movable element. However, the described embodiment examples can easily be implemented using other drive principles, such as electromagnetic force generation or sensing. The deflectable elements may, for example, be electrostatic, piezoelectric, and/or thermomechanical electrodes that provide deformation based on an applied potential. Corresponding drives are described in PCT Patent Application No. WO 002022117197 A1, for example.

The term “chamber” is used below to denote a cavity. In addition, the term “subchamber” is used to denote a subcavity.

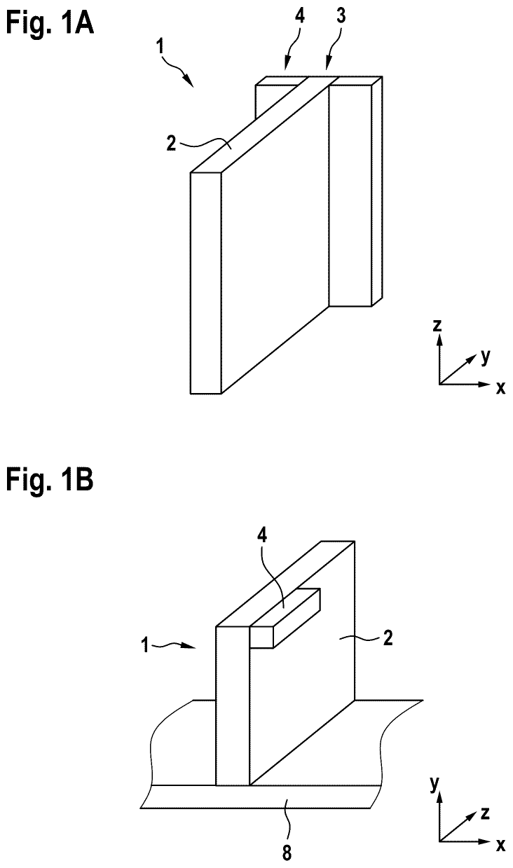

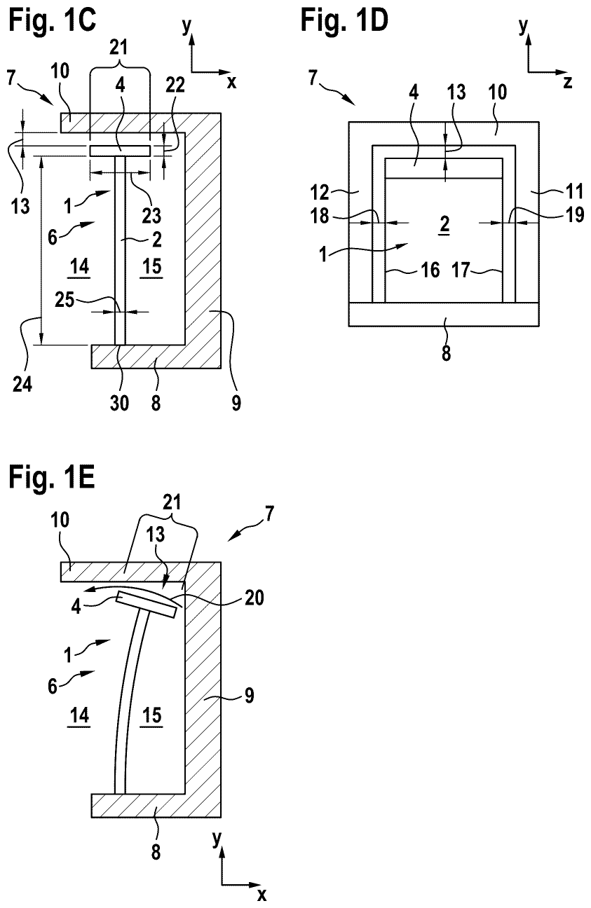

FIG. 1A shows a perspective and schematic illustration of a displacer structure 1, which comprises a lamella 2 and a cross piece 4 arranged on an edge region 3. The displacer structure 1 is formed from silicon, for example. The lamella 2 is, for example, plate-shaped and has a width along a Z direction, a length along a Y direction, and a thickness along an X direction. The cross piece 4 can project on one side or, as shown, on both sides of the lamella in the X direction beyond the side surfaces. The cross piece 4 is an embodiment of a thickened edge region of the lamella.

For example, the cross piece 4 can extend only over a portion of the edge region 3 and only over one side surface of the lamella in the X direction, as shown in FIG. 1B.

FIG. 1C shows a schematic partial cross-section through a chamber 6 of a microelectromechanical device 7 for generating and/or for detecting a fluid pressure with a displacer structure 1. The chamber 6 is bounded by multiple walls 8, 9, 10, wherein the first wall 8 forms a first boundary surface, the second wall 9 forms a second boundary surface, and the third wall 10 forms a third boundary surface. In the illustrated embodiment example, the displacer structure 1 of FIG. 1A is fastened with a fourth edge region 30 to the first wall 8. The edge region 3 with the cross piece 4 is at a specified distance 13 from the assigned third wall 10. A fluid channel 21 is formed between the edge region 3 of the lamella 2 and the wall 10, in particular between the cross piece 4 and the wall 10. The displacer structure 1 divides the chamber 6 into a first subchamber 14 and a second subchamber 15. The fluid channel 21 connects the first and second subchambers 14, 15.

FIG. 1D shows a view of the arrangement of FIG. 1C with a view onto the displacer structure 1 in a YZ plane. It can be seen that the lamella 2 with a second and a third further edge region 16, 17 is at a second and a third distance 18, 19 from assigned boundary surfaces, which are formed by a fourth and a fifth wall 4, 5 of the chamber 6.

FIG. 1E shows a schematic cross-section in the YX plane through the arrangement of FIG. 1C, wherein the displacer structure 1 is deflected in the direction toward the second subchamber 15 in this illustration. The deflection of the displacer structure 1 can be generated by active control and/or by pressure buildup in the first subchamber 14. Movement of the displacer structure 1 in the direction toward the second wall 9 pressurizes a fluid located in the second subchamber 15. The fluid attempts to flow in a fluid flow 20, which is shown in the form of an arrow, from the second subchamber 15 into the first subchamber 14 via the distance 13. The formation of the cross pieces 4, 5 lengthens the length of the flow channel 21, which is formed between the third wall 10 and the edge region 3 or the cross pieces 4, 5, in the flow direction. This makes it more difficult for the fluid to flow out of the second subchamber 15 into the first subchamber 14.

Depending on the chosen embodiment, the displacer structure 1 can be caused to deflect by the fluid in the subchamber 14 as a result of a pressure increase or by the fluid in the subchamber 15 as a result of a pressure reduction, without actively moving the displacer structure itself. In these cases, fluid also flows via the fluid channel 21 from the subchamber at the greater pressure into the subchamber at the lower pressure. In the case of active pressure generation through actively deflecting or deforming the displacer structure 1, e.g., using electrostatic and/or piezoelectric forces, a pressure difference between the subchambers 14, 15 is generated, wherein a fluid flow through the flow channel 21 arises. A flow resistance through the flow channel 21 is defined by the shape and/or the length of the displacer structure at the edge region 3 and/or the shape of the assigned boundary surface, i.e., the third wall 10, and the distance 13 between the wall 10. Both subchambers 14, 15 may be open, semi-open, or closed.

Preferred dimensions for the displacer structure 1 and the device 7 are explained with reference to FIG. 1C. The distance 13 along the Y direction between the third wall 10 and the edge region 3 of the lamella 2 or the cross piece 4 of the lamella 2 can be in the range between 0.01 μm to 100 μm, preferably between 0.1 μm to 30 μm, particularly preferably between 1 μm to 10 μm.

A thickness 22 of the cross piece 4 in the Y direction is, for example, in the range of 0.1 μm to 300 μm, preferably between 0.5 μm to 50 μm, particularly preferably between 1 μm to 10 μm. The length of the cross piece 4 in the X direction can be in the range of 0.1 μm to 300 μm, preferably 1 μm to 70 μm, particularly preferably between 5 μm to 40 μm. The length 24 of the lamella 2 along the Y direction can be in the range of 10 μm to 50 mm, preferably between 100 μm to 10 mm, particularly preferably of 200 μm to 5 mm, more particularly preferably of 300 μm to 3 mm. The length 24 of the lamella 2 extends to the underside of the first or the second cross piece 4, 5. The thickness 25 of the lamella 2 in the X direction is in the range of 0.1 μm to 300 μm, preferably between 1 μm to 10 μm, particularly preferably between 2 μm to 30 μm. Other geometries can also be used depending on the chosen embodiment.

The displacer structure 1 can be designed to be actively moved. Electrostatic, piezoelectric, or other drive systems can be used for this purpose. In addition, the displacer structure 1 can also be only passively movable, for example as a result of pressure differences in the first and/or the second subchamber 14, 15.

The fastening of the displacer structure 1 with an edge region to the first wall 8 is only by way of example. Depending on the chosen embodiment, other connecting elements or even elastic connections between the displacer structure 1 and a wall of the chamber 6 or multiple walls of the chamber can also be realized.

The cross piece 4 can be plate-shaped. However, the shape of the cross piece 4 is not limited to this shape. The cross piece 4 may also have other shapes, cross-sections, and/or sizes. A function of the cross piece 4 is to increase a flow resistance between the first and the second subchamber 14, 15. The stiffness of the lamella 2 is preferably not to be significantly increased in this case.

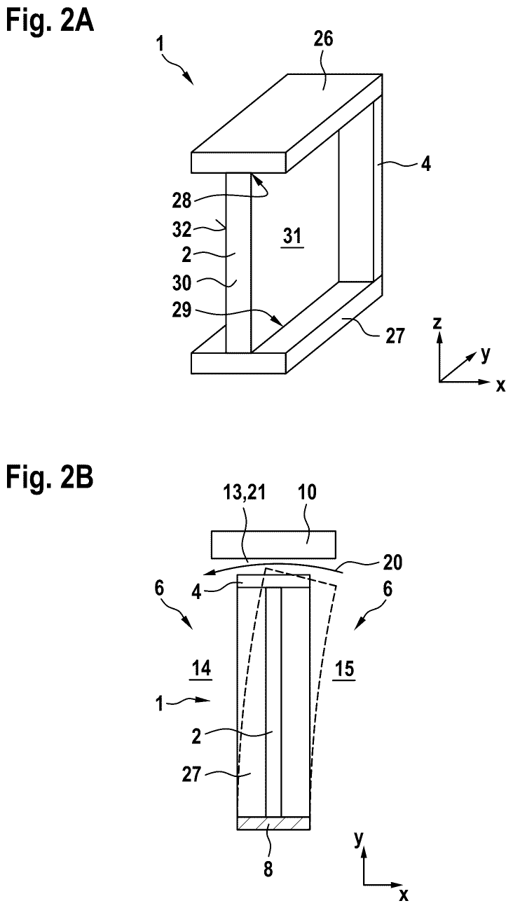

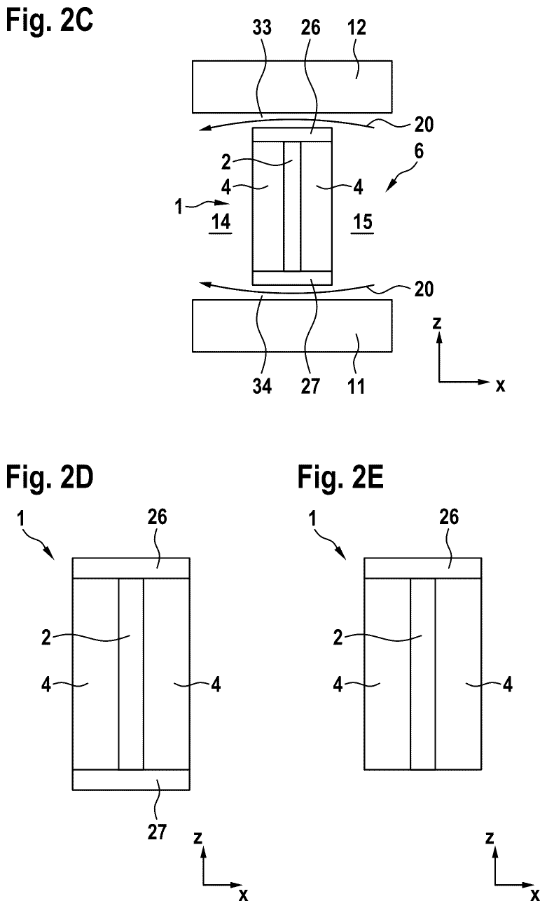

FIG. 2A shows a perspective view of a further embodiment of a displacer structure 1 comprising a lamella 2, a cross piece 4 like the embodiment of FIG. 1, and also a second cross piece 26 and a third cross piece 27. The second cross piece 26 is arranged along a second edge region 28 of the lamella 2. The second cross piece 26 extends from the edge region 3 to a fourth edge region 30 of the lamella 2. In addition, a third cross piece 27 is provided, which is arranged on a third edge region 29 of the lamella 2 and extends from the edge region 3 to the fourth edge region 30. Depending on the chosen embodiment, the cross pieces 4, 26, 27 can each have the same shape. In addition, the cross pieces 4, 26, 27 can also have different shapes. For example, the second and the third cross piece 26, 27 along the edge regions 28, 29 extend from the edge region 3 not directly to the fourth edge region 30, but end at a specified distance from the fourth edge region 30.

Depending on the chosen embodiment, the cross pieces 4, 26, 27 can extend from the lamella 2 beyond both side surfaces 31, 32 of the lamella 2. Depending on the chosen embodiment, the cross pieces 4, 26, 27 can also extend beyond only one side surface of the lamella 2. The cross pieces 4, 26, 27 can also extend beyond different side surfaces 31, 32 of the lamella 2. In addition, the cross pieces 4, 26, 27 can also extend over only a section of the corresponding edge region. The cross pieces 4, 26, 27 are preferably formed from the same material as the lamella 2, in particular with a uniform material composition from the same material as the lamella 2, for example from silicon.

The displacer structure 1 of FIG. 2A can have a width along the Z-axis in the range of 1 μm to 10 mm, preferably between 10 μm to 5 mm, particularly preferably between 15 μm to 1 mm. In addition, the second and/or the third cross piece 26, 27 can have thicknesses along the Z-axis in the range of 0.1 μm to 100 μm, preferably between 0.5 μm to 50 μm, particularly preferably between 0.5 μm to 10 μm.

FIG. 2B shows a schematic partial cross-sectional view of an arrangement of the displacer structure 1 of FIG. 2A in a chamber 6 with a subchamber 14 and a second subchamber 15. In this design, the fourth edge region 30 is fastened to the first wall 8. The edge 3 with the cross piece 4 faces the third wall 10. The distance 13 with the flow channel 21 is formed between the first cross piece 4 and the third wall 10 as a boundary surface. When the displacer structure 1 moves, for example to the right in the direction of the second subchamber 15, as shown schematically in the form of dashed lines, fluid attempts to flow from the second subchamber 15 via the flow channel 21 into the first subchamber 14. A fluid flow 20 forms.

FIG. 2C shows a cross-section in the ZX plane through the arrangement of FIG. 2. It can be seen that a flow channel 33, 34 is also formed between the second cross piece 26 and the fifth wall 12 and between the third cross piece 27 and the fourth wall 11. When the displacer structure 1 moves in the direction toward the second subchamber 15, fluid flows out of the second subchamber 15 into the first subchamber 14 via these flow channels 33, 34. The arrangement of the second and of the third cross piece 26, 27 also increases the flow resistance for the second and the third flow channel 33, 34. The distances between the second cross piece 26 and the fifth wall 12 and between the third cross piece 27 and the fourth wall 11 can be in the range of 0.01 μm to 100 μm, preferably between 0.1 μm to 30 μm, particularly preferably between 0.1 μm to 15 μm. Depending on the chosen embodiment, one of the three cross pieces 4, 26, 27 can also be dispensed with.

FIG. 2D shows the cross-section in the ZX plane through the displacer structure 1 of FIG. 2A.

FIG. 2E shows a cross-section through a further embodiment, wherein the lamella 2 in this embodiment comprises only the cross piece 4 and the second cross piece 26.

The dimensions of the distances between the second cross piece 26 and the fifth wall 12 and between the third cross piece 27 and the fourth wall 11 can have the same dimensions as between the cross piece 4 and the wall 10 of the embodiment of FIG. 1.

In addition, the embodiment of FIG. 2 can also be connected not to the first wall 5 but via other elastic elements and/or to other walls.

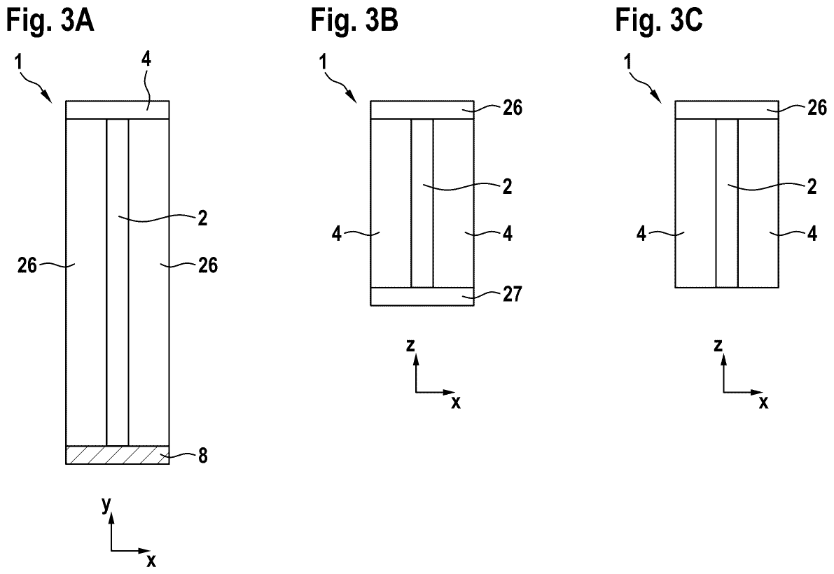

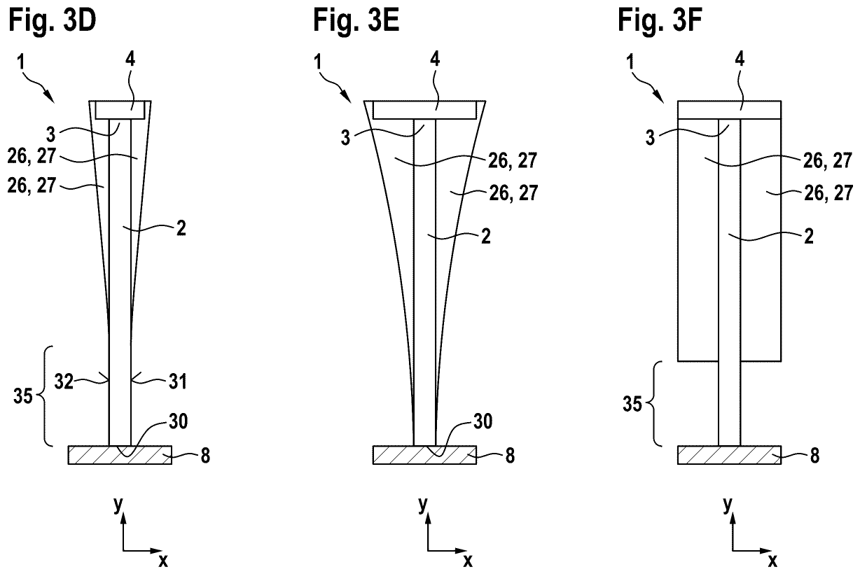

FIG. 3A to 3F show schematic partial illustrations of various embodiments of the displacer structure 1. As explained above, the displacer structure 1 can comprise a first cross piece 4 and/or a second cross piece 26 and/or a third cross piece 27, as shown schematically in FIG. 3A, 3B, and 3C. In addition, the cross pieces 26, 27 can have different shapes.

FIG. 3D shows a schematic illustration of a displacer structure 1, in which the second and/or the third cross piece 26, 27 tapers symmetrically and conically starting from the edge region 3, on which the cross piece 4 is arranged, in the direction toward the fourth edge region 30 of the lamella 2, wherein, at a specified distance 35 from the fourth edge region 30, the second and/or the third cross piece 26, 27 transitions into the first or the second side surface 31, 32 of the lamella 2. The specified distance 35 can be 10% of the total length of the lamella 2 or up to 50% or more of the length of the lamella 2 along the Y direction.

FIG. 3E shows a further embodiment of a displacer structure 1, in which the second and/or the third cross piece 26, 27 tapers starting from the edge region 3 in the direction toward the fourth edge region 30 of the lamella. The taper in this embodiment is also symmetrical for both directions from the first and second side surfaces 31, 32, wherein, however, the side edges of the second and of the third cross piece are not straight, but bent in the direction toward the first or second side surface 31, 32 of the lamella 2.

FIG. 3F shows a further embodiment of a displacer structure 1, in which the second and/or the third cross piece 26, 27 are plate-shaped in the YX plane and end at a specified distance 35 from the fourth edge 30. The second and/or the third cross piece 26, 27 have a constant width in the X direction starting from the edge region 3. The specified distance 35 can be in the range of 10% to 50% or more of the length of the lamella 2. The second and/or the third cross piece 26, 27 can have other shapes and in particular may also have combinations of the shapes shown.

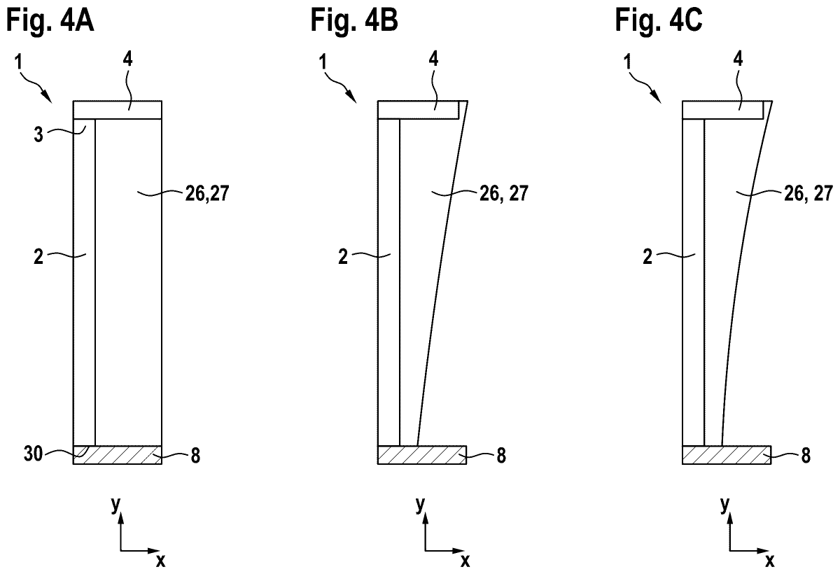

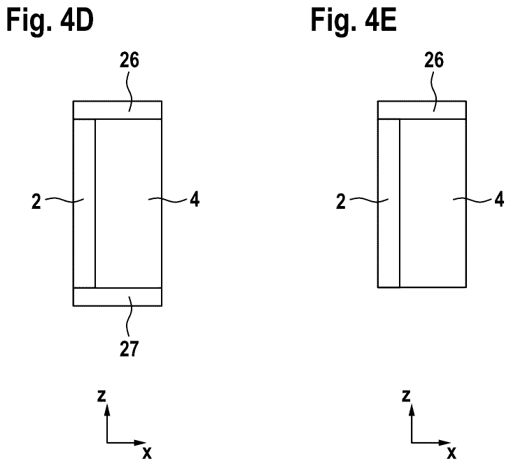

FIG. 4A shows a further embodiment of the displacer structure 1, wherein both the cross piece 4 and the second and/or the third cross piece 26, 27 in this embodiment extend away from only the first side surface 31 of the lamella 2 in the X direction.

FIG. 4A shows a schematic illustration of a side view, in which the second and/or the third cross piece 26, 27 have a constant width along the X direction starting from the first cross piece 4 to the fourth edge region 30 of the lamella.

FIG. 4B shows an embodiment in which the second and/or the third cross piece 26, 27 have a width along the X direction, starting from the first cross piece 4 in the direction toward the fourth edge region 30 of the lamella 2, which widths decrease in the direction toward the fourth edge region 30. The decrease may be continuous, for example.

FIG. 4C shows an embodiment of the displacer structure 1, in which the second and/or the third cross piece 26, 27 have a width along the X direction, which widths decrease arcuately starting from the first cross piece 4 in the direction toward the fourth region 30. In addition, further embodiments are also possible, in which combinations of the variants of FIG. 3 are also possible.

FIG. 4D shows a schematic illustration of a cross-section in the ZX plane through a displacer structure 1 of FIG. 4A with the first, second, and third cross pieces 4, 26, 27.

FIG. 4E shows a schematic illustration of a cross-section in the ZX plane through a displacer structure 1 of FIG. 4A with the first and second cross pieces 4, 26.

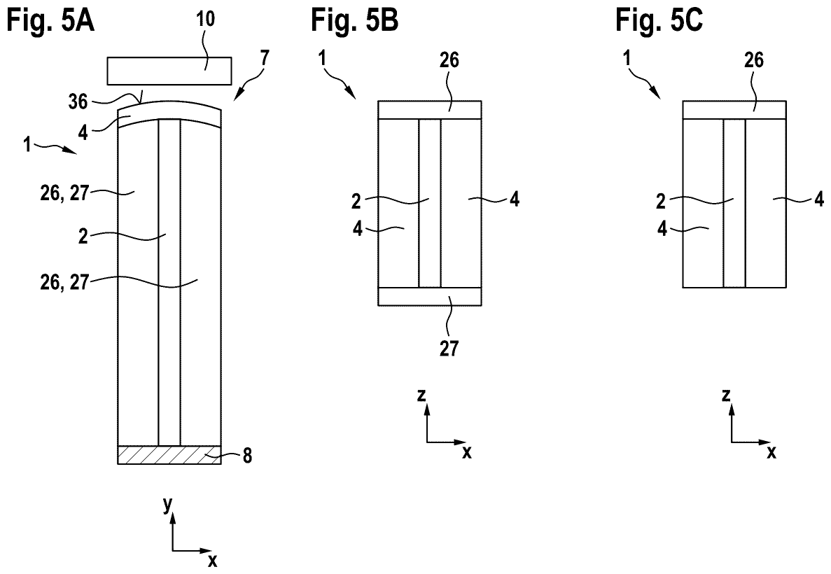

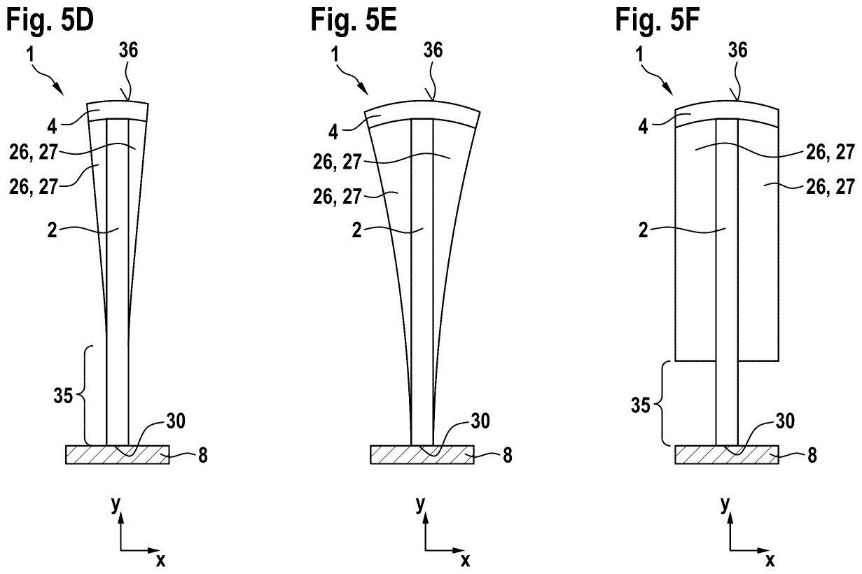

FIG. 5A to 5F show schematic illustrations of further embodiments of displacer structures, which are designed substantially according to the embodiments of FIG. 3A to 3F, wherein, however, the first cross piece 4 has a surface 36 facing the third wall 10. The surface 36 is domed in the direction toward the wall 10. For example, the surface 36 may have a specified curvature with a constant or variable radius. In addition, the first cross piece 4 can have different lengths along the X direction depending on the chosen embodiment. Accordingly, all of the displacer structures described can have domed first, second, and/or third cross pieces 4, 26, 27.

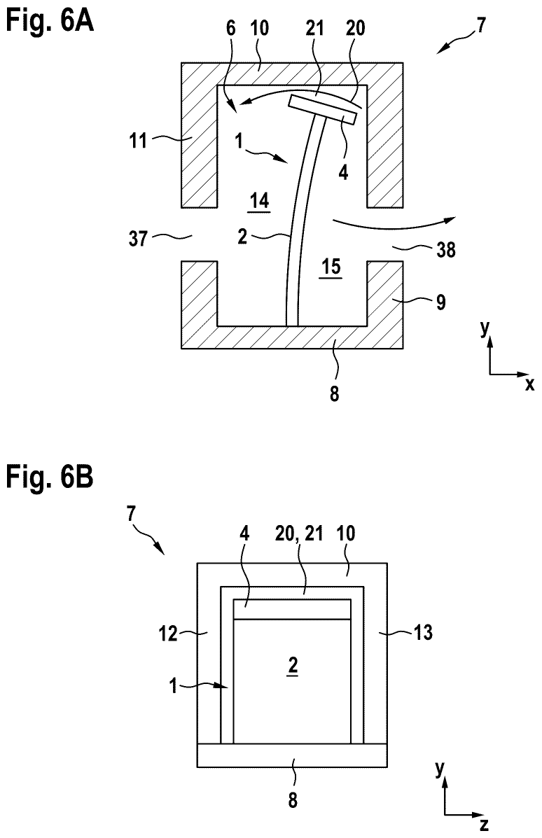

FIG. 6A shows a schematic illustration of a cross-section through a microelectromechanical device 7 with a chamber 6, a displacer structure 1 fastened with one end to a third wall 10, wherein the displacer structure 1 can have one of the forms described in all figures. For example, the device 7 may be a MEMS speaker, wherein a first opening 37 is introduced into the first subchamber 14 and a second opening 38 is introduced into the second subchamber 15. Fluid located in the second subchamber 15 moves via the second opening 38, for example, in the direction of a human ear when the displacer structure 1 is driven correspondingly. At the same time, fluid flow 20 flows out via the corresponding distances between the lamella 2 and the walls of the chamber 6.

FIG. 6B shows a schematic cross-section through the arrangement of FIG. 6A in a YZ plane.

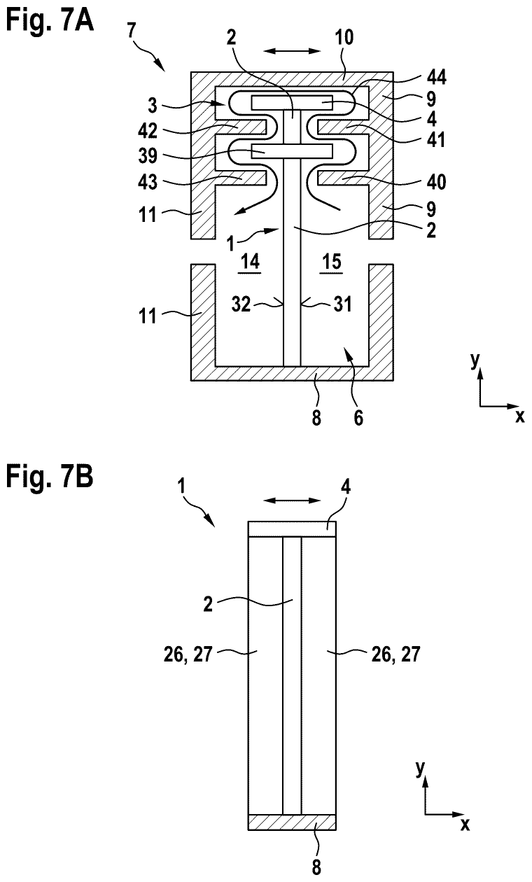

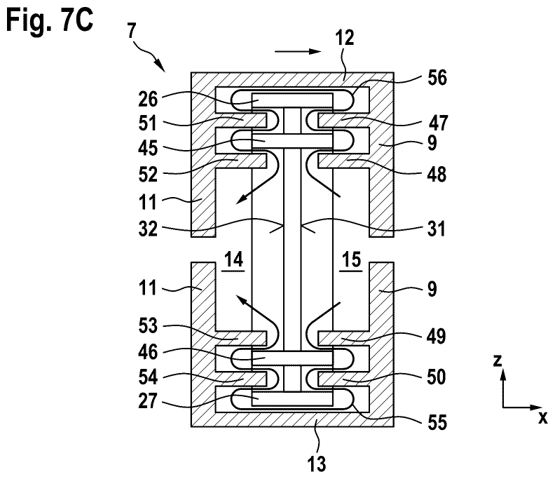

FIG. 7A shows a further embodiment of a microelectromechanical device 7 with a displacer structure 1, in which, however, the lamella 2 in the edge region 3 comprises not only a first cross piece 4 but also a fourth cross piece 39. The fourth cross piece 39 can have geometries identical to and/or different from those of the first cross piece 4. The fourth cross piece 39 is arranged at an offset from the first cross piece 4 at a specified distance from the cross piece 4 in the direction toward the fourth edge region 30. In addition, the second wall 9 of the chamber 6 comprises further cross pieces 40, 41, 42, 43, which extend laterally from the second wall 9 or the fourth wall 11 in the direction toward the lamella 2 and overlap in the X direction with the first cross piece 4 and the fourth cross piece 39. In this way, a meandering fluid channel 44 is formed between the first cross piece 4 and the boundary surfaces formed by the third wall 10 and the second and third further cross pieces 41, 42, and between the fourth cross piece 39 and the boundary surfaces formed by the further cross piece 40, 41, 42, 43 and the walls 9, 11. In this way, too, the flow resistance between the subchambers 14, 15 is additionally increased. In this embodiment as well, the lamella 2 is deflected along the X direction. The subchambers 14, 15 may each be closed, semi-open, or open. The meandering fluid channel 44 is shown schematically in the form of an arrow. The distances between the first cross piece 4 and the boundary surfaces formed by the second wall, the third wall, and the fourth wall 9, 10, 11, and the further cross pieces 40, 41, 42, 43 can be in the range of the distances explained for the embodiment of FIG. 1 with respect to the distance 13.

The distances between the fourth cross piece 39 and the boundary surfaces formed by the second wall, the third wall, and the fourth wall 9, 10, 11, and the further cross pieces 40, 41, 42, 43 can be in the range of the distances explained for the embodiment of FIG. 1 with respect to the distance 13.

Depending on the chosen embodiment, the fourth cross piece 39 and the first further cross piece 40 and the fourth further cross piece 43 in FIG. 7A can also be dispensed with. A meandering fluid channel 44 is thus already provided by arranging the second further cross piece 41 and the third further cross piece 42, even if only the first cross piece 4 is provided.

Depending on the chosen embodiment, the lamella 2 can also comprise a second and/or a third cross piece 26, 27, as shown schematically in FIG. 7B.

In addition, in the embodiment of FIG. 7B, the lamella 2 can also comprise a further second cross piece 45 in addition to the second cross piece 26 and/or a further third cross piece 46 in addition to the third cross piece 27, as shown schematically in FIG. 7C. In addition, in this embodiment, the second wall 9 can have a fifth, sixth, seventh, and eighth further cross piece 47, 48, 49, 50, which are each directed in the direction toward the first side surface 31 of the lamella 2. And, in this case, overlap with the second and/or the third cross piece 26, 27 and the further second cross piece and/or the further third cross piece 45, 46 along the X direction.

Analogously, the fourth wall 11 can comprise a further ninth, tenth, eleventh, and twelfth cross piece 51, 52, 53, 54, which extend in the direction toward the second side surface 32 of the lamella 2 and overlap in the X direction with the second and/or the third cross piece 26, 27 and/or with the further second cross piece 45 and/or the further third cross piece 46. The distances between the boundary surfaces formed by the further cross piece of the second wall 9 and/or of the fourth wall 11 and the second and/or the third and/or the further second and/or the further third cross piece 26, 27, 45, 46 can be formed according to the distances 13 of the embodiment of FIG. 1. In this way, too, further meandering fluid channels 55, 56 are formed. Depending on the chosen embodiment, the sixth, the tenth, the seventh, and the eleventh further cross piece can also be dispensed with.

The walls of the chamber 6 and/or the further cross pieces of the walls of the chamber 6 are formed, for example, from the same material as the walls of the chamber 6 and in particular from a semiconductor material, for example silicon.

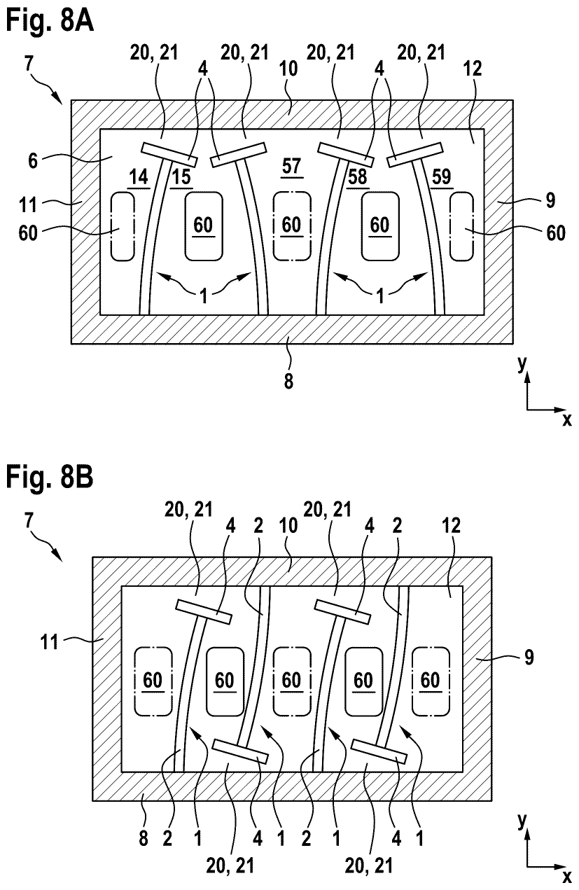

FIG. 8A shows a schematic illustration of a further embodiment of a microelectromechanical device 7 with a chamber 6 bounded by multiple walls. In the chamber 6, multiple displacer structures 1 with lamellae 2 and at least a first and/or a second and/or a third cross piece 4, 26, 27 are arranged next to one another along an X direction. The four displacer structures can have identical or different designs. The displacer structures can be designed according to one of the forms illustrated in the figures.

Between the four displacer structures, five subchambers 14, 15, 57, 58, 59 are formed. The chamber 6 is bounded by a first, second, third, fourth, fifth wall. Each of the subchambers 14, 15, 57, 58, 59 can have an opening 60. The openings 60 can be designed as inlet openings or outlet openings. In the illustrated embodiment of FIG. 8A, the lamellae are each fastened to a first wall 8 and extend with the first cross piece 4 to an opposing third wall 10. A fluid channel 21 is formed between the third wall 10 and the first cross piece 4 of the corresponding lamella, as described with reference to the previous figures. Depending on the chosen embodiment, cross pieces 26, 27 and corresponding fluid channels can also be formed at the further edge regions (not shown) of the lamella.

In addition, depending on the chosen embodiment, the lamellae can also be designed according to FIG. 7A, 7B, 7C, wherein the walls of the chambers can also be designed according to the embodiments of FIG. 7A, 7B, and 7C.

FIG. 8B shows a further embodiment of a microelectromechanical device 7 designed substantially according to the embodiment of FIG. 8A, wherein, however, the displacer structures 1 in this embodiment are alternately fastened to opposing walls 8, 10. The fluid flows 20 are thus not always formed on the same wall, but alternately on opposing walls 8, 10. The displacer structures 1 of the embodiment of FIG. 8B can be designed analogously to the displacer structures 1 of FIG. 8A.

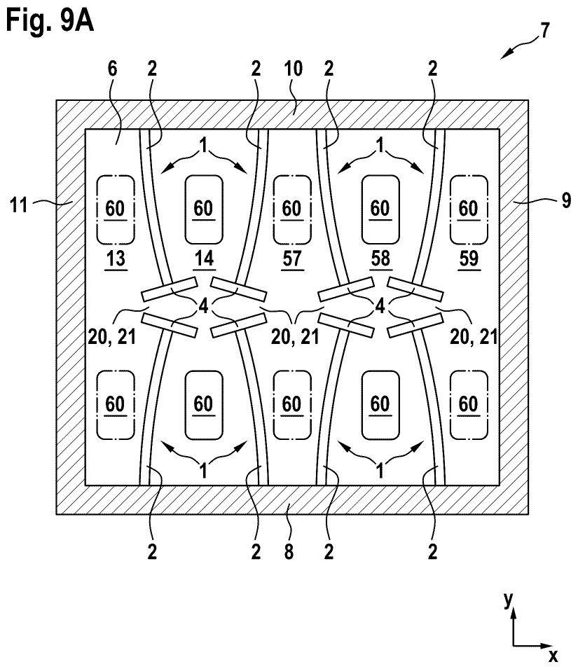

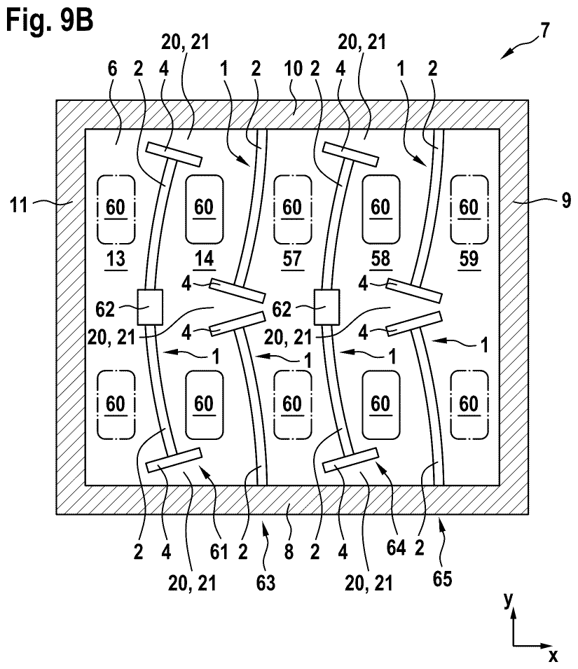

FIG. 9A shows a further embodiment of a microelectromechanical device 7, in which four pairs of displacer structures 1 are provided, wherein the four pairs of displacer structures 1 are in each case fastened to opposing walls 8, 10. In addition, each lamella 2 of the displacer structure 1 comprises at least a first cross piece 4 on the edge region 3. The cross pieces 4 of the opposing lamellae 2 are assigned to one another so that a fluid channel 21 is in each case formed between the cross pieces 4 of the assigned lamellae 2. The four pairs of displacer structures 1 bound four subchambers 13, 14, 57, 58, 59. In each of the subchambers, an opening 60 can be introduced into a wall of the chamber 6. The opposing lamellae of a pair of lamellae can in each case be designed to move in a same X direction simultaneously.

By a corresponding movement of the lamellae or by a corresponding pressure buildup in the different subchambers, an increased pressure can thus migrate from one subchamber to the next subchamber.

FIG. 9B illustrates a further example embodiment of a microelectromechanical device 7 designed substantially according to the embodiment of FIG. 9A. In this embodiment, however, a first pair of lamellae 61 is fastened in a center region of the chamber 6, for example, to a fastening block 62 with the fourth edge region 30, wherein the free end of the lamellae of the displacer structures 1 with the first cross piece 4 in each case faces opposing walls 8, 10. Thus, for the first pair of lamellae 61, the fluid channels 21 are formed between the corresponding first cross pieces 4 and the first wall 8 or the third wall 10. The second pair of lamellae 63 is in each case fastened to the opposing walls 8, 10, wherein a fluid channel 21 is formed between the facing first cross pieces 4 of the lamellae of the second pair of lamellae 63. The third pair of lamellae 64 is designed analogously to the first pair of lamellae 61. The fourth pair of lamellae 65 is designed analogously to the second pair of lamellae 63. In this way, too, a first, a second, a third, a fourth, and a fifth subchamber 13, 14, 57, 58, 59 are provided in the chamber 6, which are connected to one another in a row via fluid channels 21. Depending on the chosen embodiment, each of the subchambers can have one or more openings 60. For example, the fastening blocks 62 are only fastened to the fifth wall 12 and/or additionally to the opposing wall not shown.

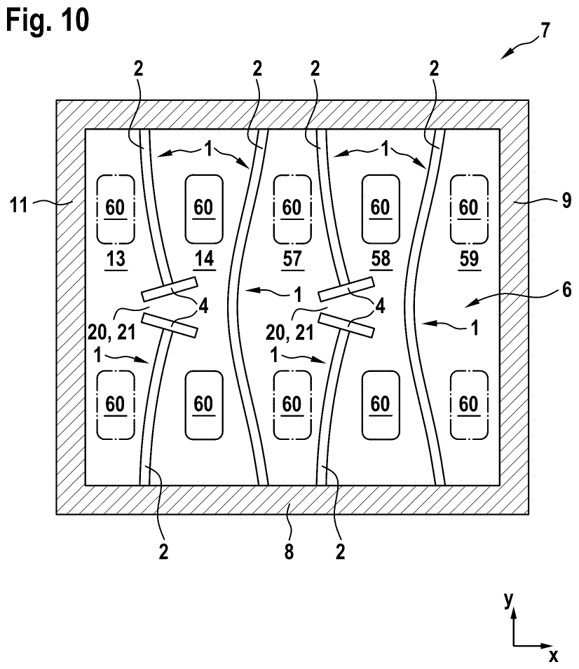

FIG. 10 shows a further embodiment of a microelectromechanical device 7 designed substantially according to the embodiment of FIG. 9A, wherein, however, instead of a second and a fourth pair of lamellae, one lamella 2 is provided in this embodiment, which lamella is connected to the opposing first and third walls 8, 10. In this embodiment as well, five subchambers 13, 14, 57, 58, 59 are formed. At least one opening 60 can be formed in each of the subchambers. The lamella 2 fastened on two sides is arranged between the second subchamber 14 and the third subchamber 57. In this embodiment, the fluid flows via the distance between the lamella 2 and the fifth wall 12 or between the lamella 2 and the sixth wall not shown, which is arranged opposite the fifth wall 12. Analogously, this is also the case for the lamella 2 that is fastened on two sides and arranged between the fourth subchamber 58 and the fifth subchamber 59.

In addition, depending on the chosen embodiment, different microelectromechanical devices 7 with chambers 6 can be designed analogously to the embodiments of FIGS. 8 to 10, wherein, however, the displacer structures 1 can be designed in any variations according to all described embodiments of FIGS. 1 to 7 and can also be provided in any embodiments and arrangements in order to realize a desired number and arrangement of subchambers.

Depending on the desired embodiments, the displacer structures 1 of the embodiments of FIGS. 8 to 10 can be designed such that they can be vibrated or moved with a 180° phase shift relative to the neighboring lamella or relative to the neighboring pairs of lamellae. In addition, the lamellae can also be designed in such a way that they can be vibrated or moved synchronously with neighboring lamellae or with neighboring pairs of lamellae.

In this way, for example, the volume of a subcavity between the displacer structures can be alternately reduced or enlarged. For fluid exchange with an environment, openings in any number and/or position can be arranged in the walls of the cavity 6 so that fluid can flow into or out of the subcavity.

For example, the described MEMS devices 7 can turn out to be MEMS-based speakers, MEMS-based microphones, MEMS-based micropumps, MEMS-based pressure sensors, or also other types of MEMS devices that interact with fluids.

1-15. (canceled)

16. A microelectromechanical device for interaction with a fluid, comprising:
a displacer structure, the displacer structure including a movable lamella that is deflectable for interaction with a fluid pressure in a pressure region of a cavity, wherein the lamella has at least one edge region, wherein the edge region of the lamella is movable along at least one boundary surface of the cavity when the lamella is deflected, wherein a flow channel is formed between the boundary surface and the edge region, wherein fluid can flow out of the pressure region via the flow channel, wherein the edge region and/or the boundary surface includes an arrangement that makes it more difficult for fluid to flow out of the pressure region via the flow channel.

17. The device according to claim 16, wherein the lamella has a width, a length, and a thickness, wherein the edge region of the lamella is thicker than the lamella at a specified distance from the edge region so that the flow channel is longer along a flow direction of the fluid.

18. The device according to claim 17, wherein the lamella in the edge region includes a cross piece projecting beyond a side surface of the lamella, wherein the cross piece projects on two opposing side surfaces of the lamella, wherein the edge region is a T shape in a cross-section perpendicular to the side surface of the lamella.

19. The device according to claim 18, wherein the cross piece extends along at least 50% of a length of the edge region of the lamella.

20. The device according to claim 17, wherein the lamella has multiple edge regions, wherein the edge regions of the lamella are moved along assigned boundary surfaces when the lamella is deflected, wherein flow channels, via which fluid can flow out of the pressure region, are formed between the boundary surfaces and the edge regions, wherein the edge regions are thicker at and/or the edge regions include cross pieces which project beyond, at least one side surface of the lamella.

21. The device according to claim 17, wherein the lamella is fastened at one side to a carrier, wherein the lamella has multiple edge regions, and wherein the lamella is thicker and/or includes a cross piece, at at least one of the edge regions.

22. The device according to claim 18, wherein the cross piece has a thickness that varies along the edge region which increases from a fastened end of the lamella in a direction of a free end of the lamella.

23. The device according to claim 18, wherein the cross piece has a surface facing the boundary surface, wherein, in a cross-section in the movement direction of the lamella, the surface has a shape that is domed in a direction of the boundary surface, wherein the domed shape has a circular shape.

24. The device according to claim 18, wherein the cross piece faces a boundary surface on each of multiple sides so that a lengthened flow channel is formed.

25. The device according to claim 18, wherein the lamella has multiple cross pieces in the edge region, wherein the cross pieces are assigned multiple boundary surfaces so that a lengthened flow channel is formed.

26. The device according to claim 25, wherein the lamella includes cross pieces at multiple edge regions, wherein the boundary surfaces are arranged on multiple edge regions.

27. The device according to claim 25, wherein the boundary surfaces are in the form of further cross pieces, and wherein the cross pieces of the lamellae and the further cross pieces overlap along an extension direction of the cross pieces and form a meandering flow channel.

28. The device according to claim 16, wherein the boundary surface is a wall of the cavity and/or a surface of a further lamella.

29. The device according to claim 16, wherein at least two lamellae are arranged in the cavity, wherein the two lamellae divide the cavity into three subcavities including a first subcavity, a second subcavity, and a third subcavity, wherein two of the subcavities separated by a lamella are in each case connected to each other via a flow channel, wherein the lamellae are deflectable in such a way that fluid can flow via fluid channels from the first subcavity into a second subcavity and/or from the second subcavity into a third subcavity.

30. The device according to claim 29, wherein the two lamellae are fastened to different walls of the cavity, and wherein the lamellae are fastened with one end and/or two ends to different walls of the cavity.
